(19) United States
(12) Patent Application Publication
(10) Pub. No.: US 2008/0157289 A1
(43) Pub. Date: Jul. 3, 2008

(54) METHOD TO ACHIEVE A LOW COST TRANSISTOR ISOLATION DIELECTRIC PROCESS MODULE WITH IMPROVED PROCESS CONTROL, PROCESS COST, AND YIELD POTENTIAL

(75) Inventors: Chris A. Nauert, Austin, TX (US); Kelley Kyle Higgins, Sr., Austin, TX (US)

Correspondence Address: AMIN, TUROCY & CALVIN, LLP, 1900 EAST NINTH STREET, 24TH FLOOR, NATIONAL CITY CENTER, CLEVELAND, OH, 44114, US

(73) Assignee: SPANSION LLC, Sunnyvale, CA (US)

(21) Appl. No.: 11/616,384

(22) Filed: Dec. 27, 2006

(51) Int. Cl. H01L 21/302; H01L 23/58

(52) U.S. Cl. 257/635; 438/693; 257/E21.214; 257/E23.002

(57) ABSTRACT

A method of processing a semiconductor structure is provided. The method includes forming a polish stop layer over one or more features on a substrate; forming a first dielectric layer over the polish stop layer, a valley portion of the first dielectric layer being just above a top of the polish stop layer; and polishing the dielectric layer down to the top of the polish stop layer. By forming a just enough dielectric layer to allow gap-fill on the substrate and polishing the dielectric layer down to the top of the polish stop layer, the method can reduce the cost and controls associated with forming the first dielectric layer.

### TECHNICAL FIELD

The subject invention generally relates to processing a dielectric isolation for use in connection with a semiconductor structure such as a memory device.

### BACKGROUND

In the semiconductor industry, there is a continuing trend toward higher device densities. To achieve these high densities there have been, and continue to be, efforts toward scaling down device dimensions (e.g., at sub-micron levels) on semiconductor wafers and to increase the number of layers of such devices on a chip. In order to accomplish such high device packing densities, smaller and smaller feature sizes are required. This may include the width and spacing of interconnecting lines, spacing and diameter of contact holes, and the surface geometry, such as corners and edges, of various features. The smaller features are separated by dielectric materials. But the formation of the dielectric isolation in small spaces is difficult to control. High packing densities are therefore difficult to achieve.

The process of manufacturing semiconductors, or integrated circuits (commonly called ICs, or chips), typically consists of more than a hundred steps, during which hundreds of copies of an integrated circuit may be formed on a single wafer. Generally, the process involves creating several patterned layers on and into the substrate that ultimately forms the complete integrated circuit. This layering process creates electrically active regions in and on the semiconductor wafer surface.

The requirement of small features with close spacing between adjacent features requires sophisticated manufacturing techniques including dielectric layer deposition and planarization of the dielectric layer. Fabricating a semiconductor structure using such sophisticated techniques may involve a series of steps including cleaning, thermal oxidation or deposition, masking, developing, etching, baking and doping.

### SUMMARY

The following presents a simplified summary of the invention in order to provide a basic understanding of some aspects of the invention. This summary is not an extensive overview of the invention. It is intended to neither identify key or critical elements of the invention nor delineate the scope of the invention. Its sole purpose is to present some concepts of the invention in a simplified form as a prelude to the more detailed description that is presented later.

One aspect of the subject invention provides a method for processing a semiconductor structure involving forming a polish stop layer over one or more features on a substrate; forming a first dielectric layer over the substrate, a valley portion of the first dielectric layer being just above the polish stop layer; and polishing the dielectric layer down to the polish stop layer. By forming a just enough dielectric layer material to allow gap-fill on the substrate and polishing the dielectric layer down to the polish stop layer, the method can reduce the cost and controls associated with forming the first dielectric layer.

Another aspect of the subject invention provides a semiconductor structure containing one or more features on a substrate; a polish stop layer over the one or more features; a first dielectric layer over the polish stop layer, and a second dielectric layer over the first dielectric layer, the second dielectric layer containing material that is different from the first dielectric layer. A top surface of the first dielectric layer is substantially coplanar with a portion of a top surface of the polish stop layer.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 illustrates a cross sectional view of an intermediate state of a portion of an exemplary semiconductor structure in accordance with one aspect of the invention.

FIG. 2 illustrates forming a polish stop layer over a substrate on which one or more features are formed in accordance with an aspect of the subject invention.

FIG. 3 illustrates forming a first dielectric layer over a substrate on which one or more features and a polish stop layer are formed in accordance with an aspect of the subject invention.

FIG. 4 illustrates polishing a first dielectric layer down to a top of a polish stop layer in accordance with an aspect of the subject invention.

FIG. 5 illustrates forming a second dielectric layer over a substrate on which one or more features, a polish stop layer, and a first dielectric layer are formed in accordance with an aspect of the subject invention.

FIG. 6 illustrates a schematic block diagram of exemplary method for processing a semiconductor structure in accordance with an aspect of the subject invention.

### DETAILED DESCRIPTION

ICs may contain more than one layer, the layers being separated by a dielectric isolation. ICs may contain one or more features on a substrate, the one or more features being separated by a dielectric isolation. Irregularities in the dielectric isolation may create problems, such as electrical shorting between features and/or layers, for example. Further, dielectric layers that are too thick may prevent achieving desired packing densities and may reduce the number of features that can be formed on an IC. Some dielectric materials are expensive and/or difficult to control, making their use undesirable. For example, borophosphosilicate glass (BPSG), while desirable, is relatively expensive. Thus, forming a layer of such dielectric material that is too thick is disadvantageous in terms of manufacturing costs. The undesirability may persist even though such materials have beneficial dielectric properties.

A BPSG layer may be formed, for example, for use as a dielectric isolation by a plasma or vapor deposition process. Ideally, such a process forms a planar surface layer of BPSG on a substrate such as a wafer, but irregularities occur both between fabrication runs and within wafers. Since planarity in BPSG layer formation is desired, local planarization may be required to achieve the desired surface plane. Thus, an efficient system and/or method for forming a dielectric layer is desired to increase chip quality.

The subject invention relates to a method of achieving a low cost isolation dielectric process with improved control and yield potential. The method involves forming an isolation dielectric layer just enough to cover one or more features (e.g., transistors) that are protected by a polish stop layer on a semiconductor substrate. Portions of the isolation dielectric layer present above the protected features are polished away, leaving the isolation dielectric layer between the protected features so that the protected features are electrically isolated from one another. Since the method does not need to form a dielectric layer having a thickness much larger than the height of the features over and in between it is formed, the method can provide reduction in cost and/or improved control for manufacturing the semiconductor structure.

The invention is now described with reference to the drawings, wherein like reference numerals are used to refer to like elements throughout. In the following description, for purposes of explanation, numerous specific details are set forth in order to provide a thorough understanding of the subject invention. It may be evident, however, that the invention can be practiced without these specific details. In other instances, well-known structures and devices are shown in block diagram form in order to facilitate describing the invention.

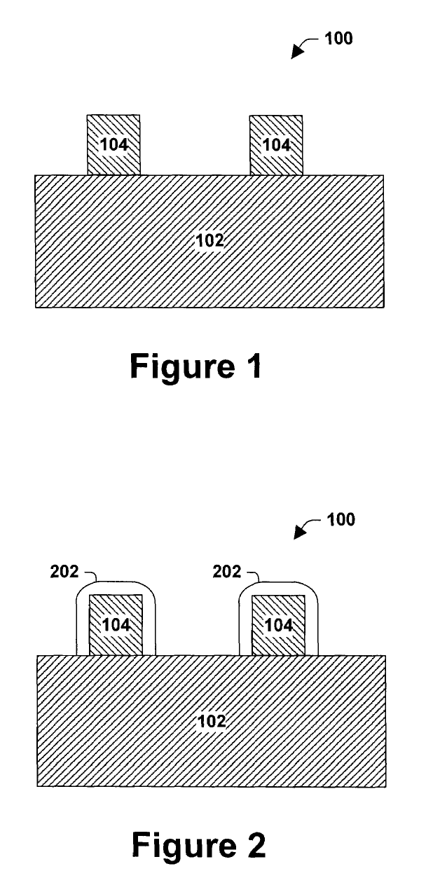

FIG. 1 illustrates a cross sectional view of an intermediate state of a portion of an exemplary semiconductor structure 100. The semiconductor structure 100 contains one or more features 104 on a substrate 102. In one embodiment, the semiconductor structure 100 is portion of a memory device. Examples of memory devices include a volatile memory and a nonvolatile memory. Examples of volatile memory include RAM such as SRAM, dynamic RAM (DRAM), synchronous DRAM (SDRAM), double data rate SDRAM (DDR SDRAM), enhanced SDRAM (ESDRAM), Synchlink DRAM (SLDRAM), Rambus direct RAM (RDRAM), direct Rambus dynamic RAM (DRDRAM), and Rambus dynamic RAM (RDRAM). Examples of nonvolatile memory include ROM, PROM, electrically programmable ROM (EPROM), electrically erasable programmable ROM (EEPROM), or flash memory.

The substrate 102 may contain any suitable substrate material on which electric device such as a transistor can be formed. When the semiconductor structure 100 is a portion of a memory device, the semiconductor structure 100 can be either a portion of high-density core regions of a nonvolatile memory device or a portion of low-density peripheral regions of a nonvolatile memory device. The high-density core region typically includes one or more M×N array cores of individually addressable, substantially identical memory cells. The low-density peripheral region typically includes input/output (I/O) circuitry and circuitry for selectively addressing the individual cells. The selective addressing circuitry typically includes one or more x-decoders and y-decoders, cooperating with the I/O circuitry for connecting the source, gate, and drain region of selected addressed cells to predetermined voltages or impedances to effect designated operations on the cell, e.g., programming, reading and erasing, and deriving necessary voltages to effect such operations.

The one or more features 104 are any suitable structure formed on the substrate 102. Examples of features 104 include transistors, vias, diodes, contacts, plugs, capacitors, lines, wires, gates, interconnects, and the like. In one embodiment, the feature 104 is a single-layer structure. In another embodiment, the feature 104 is a multi-layer structure. The multi-layer structure may include two or more layers.

When the feature 104 is a single-layer structure, the feature 104 can contain any suitable materials for the semiconductor structure 100. Examples of materials of the feature 104 include a conductive material (e.g., tungsten (W), aluminum (Al), copper (Cu), gold (Au), and silver (Ag)), a semiconductive material, a dielectric material, an insulating material, a barrier material (e.g., titanium (Ti), titanium nitride (TiN), tantalum (Ta), tantalum nitride (TaN)), and a material having desired mechanical, optical, or electrical properties.

When the feature is a multi-layer structure 104, the multi-layer structure 104 can contain layers containing any suitable materials. In one embodiment, the feature 104 contains one or more of a thin gate dielectric layer; a floating gate; an interpoly dielectric layer; a control gate; a gate silicide layer; a cap layer; a sidewall spacer, or a silicon oxynitride layer (not shown). The thin gate dielectric layer may be referred as a tunnel oxide and contain a thin layer of oxide.

The floating gate may be formed on the thin gate dielectric layer. The floating gate may contain suitable conductive polysilicon (e.g., polycrystalline silicon) and may be formed by any suitable technique, e.g., a chemical vapor deposition. The interpoly dielectric layer may be formed on the floating gate. The interpoly dielectric layer may contain any suitable dielectric material, such as, e.g., an oxide-nitride-oxide (ONO) tri-layer and an oxide-nitride (ON) bi-layer. The interpoly dielectric layer can be formed by a suitable technique, for example, where the interpoly dielectric layer is ONO, by growing a layer of oxide, depositing a layer of nitride, followed by growing another layer of oxide.

The control gate may be formed on the interpoly dielectric layer. The control gate may contain suitable conductive polysilicon (e.g., polycrystalline silicon) and may be formed by any suitable technique, e.g., a chemical vapor deposition. The gate silicide layer may be formed on the control gate. The gate silicide layer may be formed to reduce resistance. The poly cap layer may be formed on the gate silicide layer. The silicon oxynitride layer may be formed over the poly cap layer. The combination of the poly cap layer and the silicon oxynitride layer may be commonly referred to as a “passivation layer.” The sidewall spacer may or may not be formed around the thin gate dielectric layer, the floating gate, the interpoly dielectric layer, the control gate, the gate silicide layer, and the cap layer on the substrate 102.

FIG. 2 shows forming a polish stop layer 202 over a substrate 102 on which one or more features 104 are formed. The polish stop layer 202 may be any insulator material suitable for a semiconductor structure 100. The polish stop layer 202 contains a material that has a much lower or negligible polish rate compared to the polish rate of the subsequently described first dielectric layer. The polish stop layer 202 has a good etch selectivity to the first dielectric material and a low polish rate in a subsequent polishing process. For example, a polish rate of a nitride material is markedly slower than the polish rate of an oxide material with respect to an oxide etchant. Accordingly, in one embodiment, a nitride material can be employed as a polish stop layer 202 when an oxide material is used as a first dielectric layer. Examples of polish stop layer materials include silicon oxynitride (SiON), silicon nitride (SiN), and the like.

The polish stop layer 202 may be in contact with the one or more features 104 on the substrate 102 and is conformal over the features 104. The polish stop layer 202 may reduce the effective spacing in the horizontal direction between the one or more features 104. However, the benefits provided by the polish stop layer 202 outweigh the reduction of spacing.

In some embodiments, a silicon nitride may be present on the structure as an antireflection layer. The antireflection layer can be conformal over the features 104. In these instances, forming a separate polish stop layer 202 is not necessary since the silicon nitride antireflection layer can also function as a polish stop layer 202. Thus, efficiencies are created when a silicon nitride antireflection layer is employed.

The polish stop layer 202 has a suitable thickness that depends upon the desired implementations and/or the semiconductor structure 100 being fabricated. The thickness of the polish stop layer 202 may vary and is not critical to the subject invention. In one embodiment, the polish stop layer 202 has a thickness of about 10 Angstroms or more and about 5,000 Angstroms or less. In another embodiment, the polish stop layer 202 has a thickness of about 50 Angstroms or more and about 2,000 Angstroms or less. In yet another embodiment, the polish stop layer 202 has a thickness of about 100 Angstroms or more and about 1,000 Angstroms or less. The thickness of the polish stop layer 202 may be reduced during the subsequent polishing process.

The polish stop layer 202 can be formed by employing any suitable techniques including plasma and chemical vapor deposition, and the like, with an optional patterned mask, followed by an optional etching away and/or etching back one or more portions. After the formation of the polish stop layer 202, all or portions of the substrate 102 may be subject to any suitable semiconductor structure fabrication processes. General examples of semiconductor structure fabrication processes include masking, patterning, etching, planarization, thermal oxidation, implant, annealing, thermal treatment, and deposition techniques normally used for making semiconductor structures.

In one embodiment, a portion of the polish stop layer 202 positioned on the substrate 102 where the one or more features 104 are not located may be removed by etching. By way of example, FIG. 2 shows a polish stop layer 202 that remains over the one or more features 104 conformally after etching away portions of the polish stop layer 202 adjacent to the substrate 102 and between the one or more features 104. In another embodiment, a polish stop layer 202 covers a substantially entire surface of the substrate 102 (not shown).

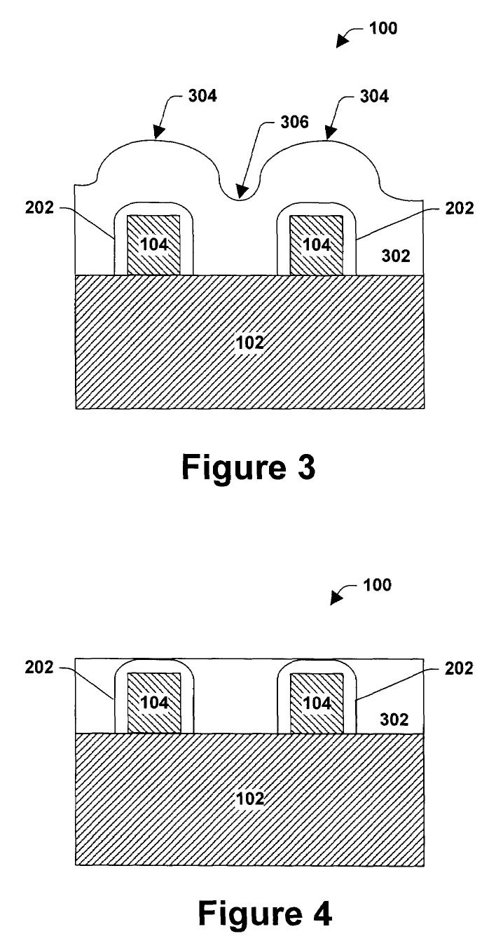

FIG. 3 shows a first dielectric layer 302 over a substrate 102 on which one or more features 104 and the polish stop layer 202 are formed. The first dielectric layer 302 may be in contact with the polish stop layer 202. The first dielectric layer 302 contains any suitable dielectric material that has a much faster polish rate compared to a polish rate of the polish stop layer 202 with respect to a certain etchant. Since a polishing rate of the first dielectric layer 302 is faster than a polishing rate of the polish stop layer 202, polishing selectivity is achieved between the first dielectric layer 302 and the polish stop layer 202.

General examples of first dielectric layers 302 include silicon based dielectric materials, oxide dielectric materials, silicates, and low k materials. Examples of silicon based dielectric materials include silicon dioxide, and silicon oxynitride. Examples of silicates include fluorine doped silicon glass (FSG), tetraethylorthosilicate (TEOS), borophosphotetraethylorthosilicate (BPTEOS), phosphosilicate glass (PSG), BPSG, and other suitable spin-on glasses. Examples of low k materials include one or more of polyimides, fluorinated polyimides, polysilsequioxane, benzocyclobutene (BCB), poly(arylene ester), parylene F, parylene N and amorphous polytetrafluoroethylene. Specific examples of a commercially available low k materials include those under the trade designations Flare™ from AlliedSignal, believed to be derived from perfluorobiphenyl and aromatic bisphenols; Black Diamond™ from Applied Materials; ALCAP-S from Asahi Chemical; SiLK® and Cyclotene® BCB from Dow Chemical; Teflon® polytetrafluoroethylene from DuPont; XLK and 3MS from Dow Corning; HSG RZ25 from Hitachi Chemical; HOSP™ and Nanoglass™ from Honeywell Electronic Materials; LKD from JSR Microelectronics; CORAL™ and AF4 from Novellus; mesoporous silica from Battelle PNNL; and Velox™ PAE-2 from Schumacher. The first dielectric layer 302 can be formed employing any suitable techniques including chemical vapor deposition and plasma enhanced chemical vapor deposition.

As shown in FIG. 3, the first dielectric layer 302 may be formed with an irregular surface. For example, there may be peaks 304 and valleys 306 in the first dielectric layer 302, creating a non-planar surface of the first dielectric layer 302. Reheating the semiconductor structure 100 can cause a reflow of the first dielectric layer 302, and can reduce the height of the peaks 304 and reduce the depths of the valleys 306. Thus, an optional reheating act causing the reflow of the dielectric material 302 may be conducted. The non-planar surface is undesirable because it may cause difficulties in subsequent processing of the semiconductor structure 100 (e.g., material waste, undesired electrical properties, expanded layer sizes).

In one embodiment, the first dielectric layer 302 is formed over the substrate 102 so that the valley portion 306 of the first dielectric layer 302 is just above the top of the polish stop layer 202 above a feature 104. When the semiconductor structure 100 is a portion of a nonvolatile memory device, the first dielectric layer 302 may be formed over the substrate 102 so that the valley portion 306 of the first dielectric layer 302 in a core region and/or a peripheral region of the nonvolatile memory device is just above the top of the polish stop layer 202 above a feature 104.

The first dielectric layer 302 has a suitable thickness so that a substantially planar surface can be achieved after polishing the first dielectric layer 302. In one embodiment, the thickness of the first dielectric layer 302 at the valley portion 306 (e.g., between features 104) is about 500 Angstroms or more and about 5,000 Angstroms or less. In another embodiment, a thickness of the first dielectric layer 302 at the valley portion 306 is about 600 Angstroms or more and about 4,000 Angstroms or less. In yet another embodiment, a thickness of the first dielectric layer 302 at the valley portion 306 is about 700 Angstroms or more and about 3,000 Angstroms or less.

In one embodiment, the thickness of the first dielectric layer 302 of the valley portion 306 is substantially equal to the height of the top of the polish stop layer 202 above a feature 104. In another embodiment, the first dielectric layer 302 is formed over the substrate 102 so that the valley portion 306 of the first dielectric layer 302 is higher than the top of the polish stop layer 202 above a feature 104 by about 500 Angstroms or less. In yet another embodiment, the first dielectric layer 302 is formed over the substrate 102 so that the valley portion 306 of the first dielectric layer 302 is higher than the top of the polish stop layer 202 above a feature 104 by about 200 Angstroms or less. In still yet another embodiment, the first dielectric layer 302 is formed over the substrate 102 so that the valley portion 306 of the first dielectric layer 302 is higher than the top of the polish stop layer 202 above a feature 104 by about 50 Angstroms or less.

FIG. 4 illustrates polishing the first dielectric layer 302 down to the polish stop layer 202. The first dielectric layer 302 is polished to provide a generally planar upper surface. The first dielectric layer 302 is polished to approximately the same level as the top of the polish stop layer 202.

The first dielectric layer 302 can be polished by any suitable polishing method that selectively polishes the dielectric layer 302 compared to the polish stop layer 202. Thus, a polishing method that has a faster polish rate of dielectric material 302 than a polish rate of the polish stop layer 202 can be employed. For example, since an oxide polishing method has a much higher oxide polish rate than a nitride polish rate, the oxide polishing method can be employed to selectively polish an oxide containing first dielectric layer 302 and not a nitride containing polish stop layer 202. In one embodiment, oxide to nitride polishing selectivity is from about 10:1 to about 1,000:1. In another embodiment, oxide to nitride polishing selectivity is from about 20:1 to about 200:1.

In one embodiment, the first dielectric layer 302 is polished by chemical-mechanical polishing (CMP). The first dielectric layer 302 can be polished under any suitable conditions to facilitate removing/polishing the first dielectric layer 302 above the polish stop layer 202. The conditions generally depend upon, for example, the thickness of the first dielectric layer 302, the composition of the first dielectric layer 302, the polishing selectivity between the first dielectric layer 302 and the polish stop layer 202, the desired implementations and/or the semiconductor structure 100 being fabricated, and the like.

The first dielectric layer 302 can be polished by applying a solid abrasive material. Applying a solid abrasive material can include applying a CMP slurry of substantially dispersed, solid abrasive material or applying a polishing pad containing solid abrasive material. Any suitable CMP slurries or any suitable polishing pads can be used to polish the first dielectric layer 302. Examples of solid abrasive materials include metal oxides such as cerium oxide, aluminum oxide, zirconium oxide, titanium dioxide; metal nitride such as titanium nitride, iron nitrate, silicon nitride; and other materials such as silicon carbide, borosilicate glass, colloidal silica, silicon carbide, graphite and diamond; mixtures thereof, and combinations thereof with other materials. The solid abrasive material may be substantially dispersed within the CMP slurry, that is, the solid abrasive material is not entirely agglomerated into floccules containing multiple solid abrasive particles.

In one embodiment, the first dielectric layer 302 is polished by ceria-CMP. In the ceria-CMP, a ceria containing CMP slurry can be employed to polish the first dielectric layer 302. The ceria-CMP may use commercially available ceria-containing slurries such as, for example, MicroPlanar® and STI2xxx™ products such as ceria slurries manufactured by DA NanoMaterials LLC, SiLect® 6000 slurry manufactured by Cabot Microelectronics Corporation, the Tizox® 8268 slurry manufactured by Ferro Corporation of Cleveland, Ohio, ceria-containing slurries manufactured by companies such as Hitachi Chemical Co., Ltd. of Tokyo, Japan and JSR Micro, Inc. of Sunnyvale, Calif.

When the first dielectric layer 302 contains an oxide material such as BPSG and the polish stop layer 202 contains a nitride material such as silicon nitride, the ceria-CMP can selectively and/or preferentially remove the first dielectric layer 302 and not the polish stop layer 202. The ceria-CMP can selectively and/or preferentially polish the first dielectric layer 302 while leaving most of the polish stop layer 202. Due to the high oxide-to-nitride selectivity and/or preferentiality of the ceria-based slurry, the ceria-CMP has a low nitride polish rate compared to its oxide polish rate. At the end of the ceria-CMP, the surface of the first dielectric layer 302 may have excellent planarity relative to a surface polished using only a silica-CMP process.

For example, ceria containing slurries have oxide polish rates of about 1000 Angstroms/min while their nitride polish rates are only about 10 Angstroms/min. Unlike silica-based slurries that polish 1 Angstrom of nitride for every 4 Angstroms of oxide, ceria based slurries polish 1 Angstrom of nitride for every 100 Angstroms of oxide. In one embodiment, the oxide to nitride selectivity of the ceria-CMP is at least about 10:1. In another embodiment, the oxide to nitride selectivity of the ceria-CMP is at least about 25:1. In yet another embodiment, the oxide to nitride selectivity of the ceria-CMP is at least about 50:1.

Any suitable commercially available CMP slurry other than the ceria-containing slurries and any suitable polishing pad can be employed as long as the first dielectric layer 302 can be removed down to the top of the polish stop layer 202. Examples of polishing pads that can be used for the CMP include hard urethane pads, for example, manufactured by Rohm and Haas Electronic Materials CMP Technologies, urethane pads manufactured by JSR Micro, Inc., or any suitable polishing pads including soft polishing pads.

The first dielectric layer 302 can be polished by CMP under any suitable conditions to facilitate removing/polishing the first dielectric layer 302 without substantially removing the polish stop layer 202. By way of example, the first dielectric layer 302 can be polished by CMP under the following conditions. The semiconductor structure 100 containing the first dielectric layer 302 may have a rotation speed at about 10 RPM or more and about 300 RPM or less. A polish pressure applied is about 0.5 psi or more and about 7 psi or less. The CMP slurry may flow at a rate of about 50 ml/min or more and about 500 ml/min or less. The first dielectric layer 302 may be polished at a temperature of about 5 degrees Celsius or more and about 60 degrees Celsius or less. The polish time may depend upon the amount of dielectric material that is being removed by the CMP. In one embodiment, the first dielectric layer 302 may be polished for about 1 second or more and about 10 minutes or less. The slurry used in the CMP may be diluted in water, such as de-ionized water, to produce an aqueous dilution of the slurry having a desired concentration of solid abrasive material. For example, the aqueous dilution of the slurry may contain about 0.1 wt % or more of solid abrasive material and about 3 wt % or less of solid abrasive material. The slurry may contain a surfactant. In one embodiment, the surfactant may be cationic. Examples of cationic surfactants include quaternary ammonium salts, such as a quaternary ammonium halide.

In one embodiment, the first dielectric layer 302 is polished until the polishing pad contacts the polish stop layer 202 or the top of the polish stop layer 202 is exposed. As a result, polishing the first dielectric layer 302 may not substantially remove the polish stop layer 202, or may remove very little or no polish stop layer material 202. In another embodiment, polishing the first dielectric layer 302 is terminated on the top of the polish stop layer 202. In yet another embodiment, the first dielectric layer 302 is polished until a polishing pad reaches the valley portion 306 of the first dielectric layer 302. As a result, polishing the first dielectric layer 302 may remove only the peak portions 304 of the first dielectric layer 302. As a result of polishing the first dielectric layer 302, the top of the polish stop layer 202 may contain substantially no first dielectric layer 302.

After polishing the first dielectric layer 302, an exposed surface (e.g., top surface) of polished first dielectric layer 302 may be substantially coplanar with an exposed surface (e.g., top surface) of the polish stop layer 202. In one embodiment, the resultant top surface of the first dielectric layer 302 is higher than the top of the polish stop layer 202 by about 10 Angstroms or less. In another embodiment, the resultant top surface of the first dielectric layer 302 is higher than the top of the polish stop layer 202 by about 5 Angstroms or less. In yet another embodiment, the resultant top surface of the first dielectric layer 302 is higher than the top of the polish stop layer 202 by about 3 Angstroms or less.

By forming a just enough first dielectric layer 302 to allow gap-fill on the substrate 102 and polishing the dielectric layer 302 down to the top of the polish stop layer 202, the method can reduce the cost and controls associated with forming the first dielectric layer 302. For example, when the first dielectric layer 302 contains BPSG that is relatively expensive, the method can reduce the cost while maintaining benefits of the BPSG first dielectric layer 302 such as conformality to transistor topography, flow capability at low temperatures, and gettering nature of phosphorous. As a result, a combination of forming a just enough first dielectric layer 302 to allow gap-fill on the substrate 102 and polishing the first dielectric layer 302 down to the polish stop layer 202 provides a significant advantage associated with manufacturing semiconductor structures.

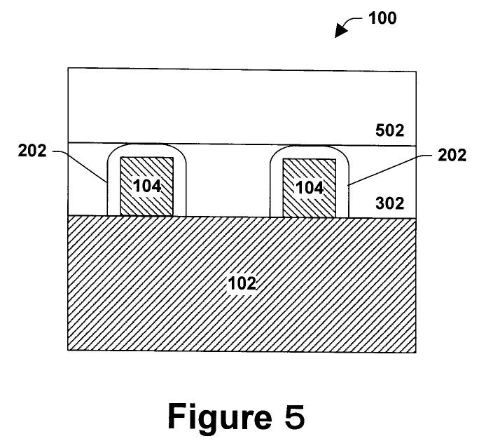

FIG. 5 illustrates formation of a second dielectric layer 502 over the first dielectric layer 302. A second dielectric layer 502 may or may not be formed on the first dielectric layer 302. The second dielectric layer 502 contains any suitable dielectric material or insulating material for providing, for example, an inter-layer dielectric (ILD). Examples of dielectric materials or insulating materials include silicon based dielectric materials, silicates, and low k materials. Examples of silicon based dielectric materials include silicon dioxide, silicon nitride and silicon oxynitride. Examples of silicates include FSG, TEOS, BPTEOS, PSG, BPSG, and other suitable spin-on glasses.

In one embodiment, the second dielectric layer 502 contains TEOS. In another embodiment, the second dielectric layer 502 contains material that is different from the first dielectric layer material 202. For example, the first dielectric layer 302 contains BPSG and the second dielectric layer 502 contains TEOS. The second dielectric layer 502 can be formed by employing any suitable techniques including chemical vapor deposition and plasma enhanced chemical vapor deposition.

In one embodiment, the second dielectric layer 502 is not polished to planarize the surface of the second dielectric layer 502. That is, the method may not include polishing the surface of the second dielectric layer 502. This is because there may be no need to polish the second dielectric layer 502 due to the planarity achieved during polishing the first dielectric layer 302. Since there is no need to polish the second dielectric layer 502, this reduces damages to another layer such as a bottom anti-reflective coating (BARC) layer (not shown) and mitigates/prevents shorts/micro-scratches at another layer such as a contact layer (now shown) associated with the semiconductor structure 100.

The second dielectric layer 502 has a suitable thickness that depends upon the desired implementations and/or the semiconductor structure 100 being fabricated. In one embodiment, the second dielectric layer 502 has a thickness of about 1,000 Angstroms or more and about 4,000 Angstroms or less. In another embodiment, the second dielectric layer 502 has a thickness of about 1,500 Angstroms or more and about 3,500 Angstroms or less. In yet another embodiment, the second dielectric layer 502 has a thickness of about 2,000 Angstroms or more and about 3,000 Angstroms or less.

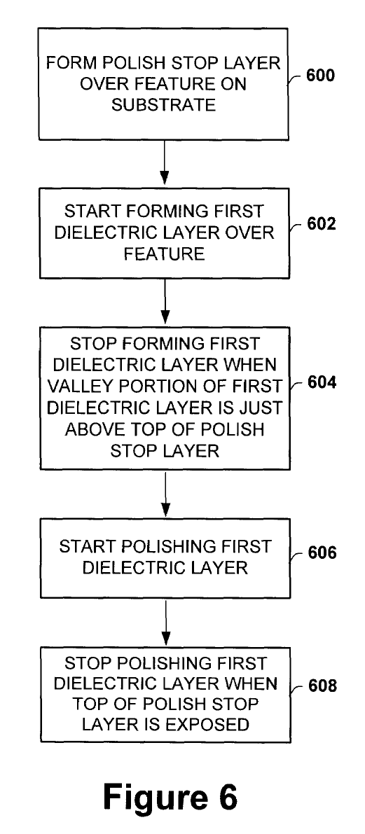

FIG. 6 illustrates an exemplary methodology of processing a dielectric isolation for use in connection with a semiconductor structure such as a memory device. At 600, a polish stop layer is formed over one or more features on a substrate. At 602, a first dielectric layer is formed over the one or more features on the substrate. At 604, the formation of the first dielectric layer is terminated when the first dielectric layer is formed just enough to fill the gap between features on the substrate. That is, the formation of the first dielectric layer is terminated when a valley portion of the first dielectric layer is just above the top of the polish stop layer. At 606, the first dielectric layer is polished down to the top of the polish stop layer. At 608, polishing the first dielectric layer is terminated when the top of the polish stop layer is exposed. A second dielectric layer may or may not be formed on the polished first dielectric layer (not shown).

Although not shown, the methodology of FIG. 6 may include any suitable semiconductor structure fabrication processes. General examples of semiconductor structure fabrication processes include masking, patterning, etching, planarization, thermal oxidation, implant, annealing, thermal treatment, and deposition techniques normally used for making semiconductor structures.

The resultant semiconductor structure formed herein can be employed for, for example, central processing units (CPUs); volatile memory devices such as DRAM devices, SRAM devices, and the like; input/output devices (I/O chips); and non-volatile memory devices such as EEPROMs, EPROMs, PROMs, and the like.

The resultant semiconductor structure formed herein is useful in any electronic device such as a memory. For example, the resultant semiconductor structure is useful in computers, appliances, industrial equipment, hand-held devices, telecommunications equipment, medical equipment, research and development equipment, transportation vehicles, radar/satellite devices, and the like. Hand-held devices, and particularly hand-held electronic devices, achieve improvements in portability due to the small size and lightweight of the memory devices. Examples of hand-held devices include cell phones and other two way communication devices, personal data assistants, Palm Pilots, pagers, notebook computers, remote controls, recorders (video and audio), radios, small televisions and web viewers, cameras, and the like.

What has been described above includes examples of the subject invention. It is, of course, not possible to describe every conceivable combination of components or methodologies for purposes of describing the subject invention, but one of ordinary skill in the art may recognize that many further combinations and permutations of the subject invention are possible. Accordingly, the subject invention is intended to embrace all such alterations, modifications and variations that fall within the spirit and scope of the appended claims. Furthermore, to the extent that the term “includes” and “involves” are used in either the detailed description or the claims, such terms are intended to be inclusive in a manner similar to the term “comprising” as “comprising” is interpreted when employed as a transitional word in a claim.

What is claimed is:

1. A method of improving isolation between one or more features on a semiconductor structure, comprising:
forming a polish stop layer over one or more features on a substrate;
forming a first dielectric layer over the polish stop layer, a valley portion of the first dielectric layer being just above a top of the polish stop layer; and
polishing the first dielectric layer down to the top of the polish stop layer to form a substantially planar surface.

2. The method of claim 1, wherein the semiconductor structure is a portion of a nonvolatile memory device, and forming the first dielectric layer is terminated when the valley portion of the first dielectric layer in a core region and/or a peripheral region of the nonvolatile memory device is just above the top of the polish stop layer.

3. The method of claim 1, wherein forming the first dielectric layer is terminated when the valley portion of the first dielectric layer is higher than the top of the polish stop layer by about 500 Angstroms or less.

4. The method of claim 1, wherein polishing the first dielectric layer is terminated when a portion of the top of the polish stop layer is exposed.

5. The method of claim 1, wherein polishing the first dielectric layer is terminated when a polishing pad reaches a valley portion of the first dielectric layer.

6. The method of claim 1, wherein polishing the first dielectric layer is terminated when a peak portion of the first dielectric layer is removed.

7. The method of claim 1, wherein polishing the first dielectric layer does not substantially remove the polish stop layer.

8. The method of claim 1, wherein the first dielectric layer is polished by a ceria-CMP and an oxide to nitride selectivity of the ceria-CMP is at least about 10:1.

9. The method of claim 1 further comprising forming a second dielectric layer over the substantially planar surface of the first dielectric layer.

10. The method of claim 1 further comprising removing a portion of the polish stop layer on the substrate before forming the first dielectric layer.

11. The method of claim 1 further comprising heating the first dielectric layer to reflow the first dielectric layer material.

12. A method of processing a semiconductor structure, comprising:
forming a polish stop layer over one or more transistors on a substrate;
forming a first dielectric layer over the polish stop layer, a valley portion of the first dielectric layer being just above a top of the polish stop layer; and
polishing the first dielectric layer until a portion of the top of the polish stop layer is exposed.

13. The method of claim 12, wherein polishing the first dielectric layer is terminated when a peak portion of the first dielectric layer is removed.

14. The method of claim 12, wherein polishing the first dielectric layer is terminated when a polishing pad reaches a valley portion of the first dielectric layer.

15. A semiconductor structure, comprising:
one or more features on a substrate;
a polish stop layer over the one or more features;
a first dielectric layer over the polish stop layer, a top surface of the first dielectric layer being substantially coplanar with a portion of a top surface of the polish stop layer, and
a second dielectric layer over the first dielectric layer, the second dielectric layer comprising material that is different from the first dielectric layer material.

16. The semiconductor structure of claim 15, wherein the first dielectric layer comprises boro-phosphosilicate glass and the second dielectric layer comprises tetraethyl orthosilicate.

17. The semiconductor structure of claim 15, the top surface of the polish stop layer is contacted with the second dielectric layer.

18. The semiconductor structure of claim 15, wherein the portion at the top of the polish stop layer contains substantially no first dielectric layer.

19. The semiconductor structure of claim 15, wherein the one or more features comprises one or more of a thin gate dielectric layer, a floating gate, an interpoly dielectric layer, a control gate, a silicide layer, a poly cap layer, a sidewall spacer, or a silicon oxynitride layer.

20. The semiconductor structure of claim 15, wherein the first dielectric layer comprises boro-phosphosilicate glass and the polish stop layer comprises silicon nitride.
